(19) United States
(12) Patent Application Publication
(10) Pub. No.: US 2005/0133801 A1
(43) Pub. Date: Jun. 23, 2005

(54) Red fluorescent material, white light emitting diode using red fluorescent material, and lighting device using white light emitting diode

(75) Inventors: Ryo Yoshimatsu, Shinagawa-ku (JP); Hisashi Yoshida, Shinagawa-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION

(21) Appl. No.: 11/013,879

(22) Filed: Dec. 17, 2004

(30) Foreign Application Priority Data
Dec. 19, 2003 (JP) 2003-422348

(51) Int. Cl. H01L 27/15; H01L 21/00

(52) U.S. Cl. 257/81; 257/432; 438/24; 438/65

(57) ABSTRACT

The present invention achieves improvement of the color reproducibility, color rendering properties and light emitting efficiency of a white light emitting diode. The present invention is a red fluorescent material composed of a europium doped calcium lanthanum tungstate represented by a general formula of Ca₃(La₁₋ₓ,Euₓ)₂W₂0₁₂ (0<x≦1). The red fluorescent material can efficiently converts light in the light emission wavelength range from 350 to 410 nm of an ultraviolet light emitting diode into red light, and can efficiently converts blue light at 465 nm and green light at 538 nm into red light.

### BACKGROUND OF THE INVENTION

1. Field of the Invention

The present invention relates to a red fluorescent material; a white light emitting diode using the red fluorescent material; a lighting device, a light emitting diode display, and a backlight unit for a liquid crystal display, these devices and unit using the white light emitting diode; and a liquid crystal display using the backlight unit.

2. Description of the Related Art

Light emitting diodes are different in light emitting mechanism from currently used light fixtures such as incandescent bulbs and fluorescent bulbs, and are compact and bright; the electric power consumption of light emitting diodes is about one-eighth the electric power consumption of bulbs having the same brightness and about one-half the electric power consumption of fluorescent lamps having the same brightness, and thus, light emitting diodes have properties excellent in energy saving. Additionally, light emitting diodes are long in operation life, excellent in shock resistance, compact and lightweight, free from yielding such harmful wastes as derived from conventional light sources, and accordingly can be used as excellent light sources in harmony with the environment.

As white light emitting diodes, known are those disclosed in Japanese Patent Nos. 2900928, 2998696, 2927279, etc. which use: light emitting diodes using nitride semiconductors and emitting blue or blue-green light; and a fluorescent material in which Ce is doped in a YAG based oxide matrix lattice (YAG:Ce fluorescent material, hereinafter abbreviated as YAG based yellow fluorescent material) known by a composition formula of (Y,Gd)₃(Al,Ga)₅O₁₂, the fluorescent material being excited by the blue or blue-green light emission of the above described light emitting diodes to emit yellow fluorescence to be complementary to the light emission of the light emitting diodes. In white light emitting diodes of this type, fluorescent materials are dispersed in the sealing resin portion enclosing each light emitting diode. Additionally, Japanese Patent Laid-Open No. 11-46015 discloses a white light emitting diode in which a non-particulate fluorescent material layer is formed as a film on a blue light emitting diode.

Additionally, National Publication of International Patent Application No. 2000-509912 discloses a three-wavelength type white light emitting diode in which are combined three visible light emitting fluorescent materials respectively emitting red light (590 nm to 630 nm), green light (520 nm to 570 nm) and blue light (430 nm to 490 nm) caused by an ultraviolet light emitting diode emitting short wavelength near ultraviolet light (370 to 410 nm). The white light emitting diode includes an ultraviolet light emitting diode disposed inside a transparent resin portion formed in a dome shape on a transparent substrate (a front panel). In the transparent resin portion are admixed three types of fluorescent material powders respectively emitting red, green and blue light caused by ultraviolet light. The surface of the transparent resin portion is subjected to mirror finish so as to work as a mirror.

National Publication of International Patent Application No. 2000-509912 discloses Y₂O₂S:Eu³⁺ as a red light emitting fluorescent material with an ultraviolet emitting diode composed of InGaN or GaN as exciting light source.

These white light emitting diodes are low in electric power consumption and long in operation life, and hence have began to be used in the fields of lighting systems, displays, liquid crystal display and the like.

White light emitting diodes, using the blue or blue-green light emission and yellow fluorescence complementary to the blue or blue-green light emission, are used for backlight units of a liquid crystal display and for light emitting diode displays. However, the white light emitting diodes having such structures as described above are poor in color reproducibility and color rendering properties because of insufficient light emitting intensity in the red region; thus, improvement of these problems have been demanded.

Additionally, a white light emitting diode using an ultraviolet light emitting diode, disclosed in National Publication of International Patent Application No. 2000-509912, has a high light emission efficiency in the light emission wavelengths from 370 nm to 410 nm of the ultraviolet light emitting diode, and particularly, has a highest light emission efficiency at wavelengths around 390 nm. On the contrary, a red light emitting fluorescent material of Y₂O₂S:Eu⁺³ efficiently absorbs light of 370 nm wavelength, and hence the light emission efficiency is not sufficient when an ultraviolet light emitting diode is used as an excitation source; thus, demanded is a material which can be an ultraviolet light emitting diode for the wavelength around 390 nm and has a further higher light emitting efficiency.

### SUMMARY OF THE INVENTION

The present invention is a red fluorescent material including a europium doped calcium lanthanum tungstate represented by a general formula of Ca₃(La₁₋ₓ,Euₓ)₂W₂0₁₂ (0<x≦1).

The present invention is a white light emitting diode comprising an ultraviolet light emitting diode emitting ultraviolet light, and a blue fluorescent material, a green fluorescent material and a red fluorescent material respectively emitting blue, green and red fluorescence which are disposed at least in the area, to be irradiated with said ultraviolet light, on the light emitting surface of the ultraviolet light emitting diode; and thus the white light emitting diode emitting white light through the blue, green and red fluorescence, wherein the red fluorescent material is composed of the red fluorescent material comprising the europium doped calcium lanthanum tungstate represented by the general formula of Ca₃(La₁₋ₓ,Euₓ)₂W₂0₁₂ (0<x≦1).

Additionally, the present invention is a white light emitting diode comprising a light emitting diode emitting light at least in any of the wavelength regions ranging from blue to green light; a yellow fluorescent material emitting yellow light, caused by the above described light emission, to be complementary to the above described light emission; and a red fluorescent material emitting red light; wherein the yellow fluorescent material and the red fluorescent material are disposed at least in the area, to be irradiated with the light emission from said light emitting diode, on the light emitting surface of said light emitting diode. Additionally, it is preferable that the red fluorescent material emits red light upon receiving yellow fluorescence, and in this case, it is more preferable that the yellow fluorescent material is a YAG based yellow fluorescent material. It is preferable that the red fluorescent material is a red fluorescent material composed of the europium doped calcium lanthanum tungstate represented by the general formula of Ca₃(La₁₋ₓ,Euₓ)₂W₂0₁₂ (0<x≦1).

Additionally, the white light emitting diode is a lighting system, a light emitting diode display or a backlight unit of a liquid crystal display, and a liquid crystal display using the white light emitting diode as the backlight unit.

Additionally, the present invention is a method for producing a red fluorescent material comprising a europium doped calcium lanthanum tungstate, obtained by calcing at least a calcium compound, a lanthanum compound, a europium compound and a tungsten compound, and represented by the general formula of Ca₃(La₁₋ₓ,Euₓ)₂W₂0₁₂ (0<x≦1), wherein the calcined substance obtained by calicing is recalcined at least after pulverization thereof.

The red fluorescent material of the present invention is excited by the light wavelength region of an ultraviolet light emitting diode, and also is excited by the light emission region of a light emitting diode emitting blue or green light, and emits red light in high efficiency.

Consequently, when the red fluorescent material of the present invention is used as the red fluorescent material of a white light emitting diode using an ultraviolet light emitting diode, a white light emitting diode emitting light in a high efficiency can be obtained.

Additionally, by using the red fluorescent material of the present invention in a manner admixed in a white light emitting diode including a blue or green light emitting diode and a fluorescent material which is excited by the light emitted by a blue or green light emitting diode to emit yellow light to be complementary to the light emitted by the blue or green light emitting diode, a red component can be added to the yellow light to be complementary to the light emitted by the blue or green light emitting diode, and consequently, there can be obtained a white light emitting diode which is excellent in color reproducibility and is improved in color rendering property.

### BRIEF DESCRIPTION OF THE DRAWING

FIG. 1. Eu concentration dependence of the light emission peak intensity in Ca₃(La₁₋ₓ,Euₓ)₂W₂0₁₂ (0<x≦1) prior to recalcination (relative light emission peak intensity with respect to Y₂0₂S:Eu³⁺; excitation wavelength: 394 nm).

FIG. 2. Eu concentration dependence of the X and Y values of the tristimulus values in the XYZ color system in Ca₃(La₁₋₁,Euₓ)₂W₂0₁₂ (0<x≦1) prior to recalcination (comparison between the excitation intensities of Y₂0₂S:Eu³⁺ (Comparative Example) and LiLa_{0.6}Eu_{0.4}Nb₂0₇ (Example 4)).

FIG. 3. Comparison between the excitation spectra of Y₂0₂S:Eu³⁺ (Comparative Example) and LiLa_{0.6}Eu_{0.4}Nb₂0₇ (Example 4).

FIG. 4. Comparison between the light emission spectra of Y₂0₂S:Eu³⁺ (Comparative Example) and Ca₃(La_{0.6},Eu_{0.4})₂W₂0₁₂ prior to recalcination (Example 4-1).

FIG. 5. Eu concentration dependence of the light emission peak intensity in Ca₃(La₁₋ₓ,Euₓ)₂W₂0₁₂ (0<x≦1) subsequent to recalcination.

FIG. 6. Eu concentration dependence of the X and Y values of the tristimulus values in the XYZ color system in Ca₃(La₁₋ₓ,Euₓ)₂W₂0₁₂ (0<x≦1) subsequent to recalcination.

FIG. 7. Comparison between the excitation spectra of Y₂0₂S:Eu³⁺ (Comparative Example) and Ca₃(La_{0.3},Eu_{0.7})₂W₂0₁₂ subsequent to recalcination (Example 7-2).

FIG. 8. Comparison between the light emission spectra of Y₂0₂S:Eu³⁺ (Comparative Example) and Ca₃(La_{0.3},Eu_{0.7})₂W₂0₁₂ subsequent to recalcination (Example 7-2).

### DETAILED DESCRIPTION OF THE INVENTION AND PREFERRED EMBODIMENTS

The present inventors, as a result of an elaborate research and development of a red fluorescent material, discovered a red fluorescent material formed of a europium doped calcium lanthanum tungstate, composed of calcium (Ca), lanthanum (La), europium (Eu), tungsten (W) and oxygen (O), and represented by a general formula of Ca₃(La₁₋ₓ,Euₓ)₂W₂0₁₂ (0<x≦1).

A first embodiment of the present invention is the red fluorescent material.

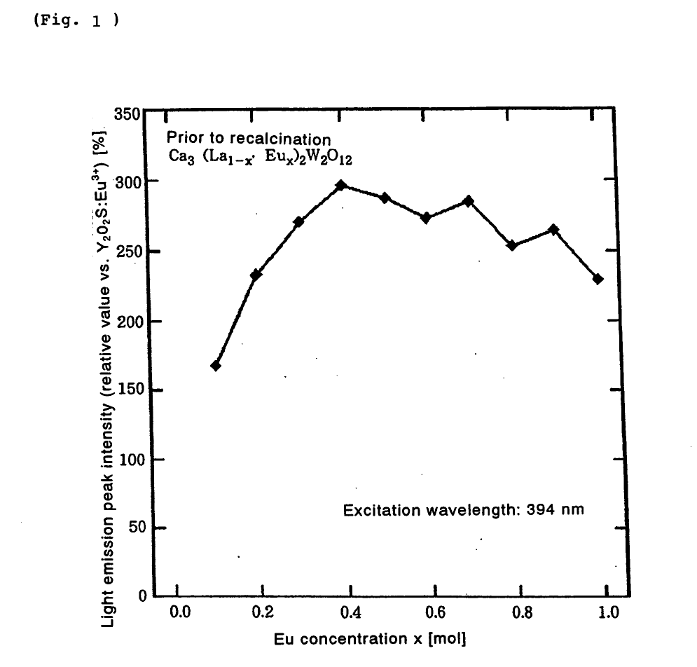

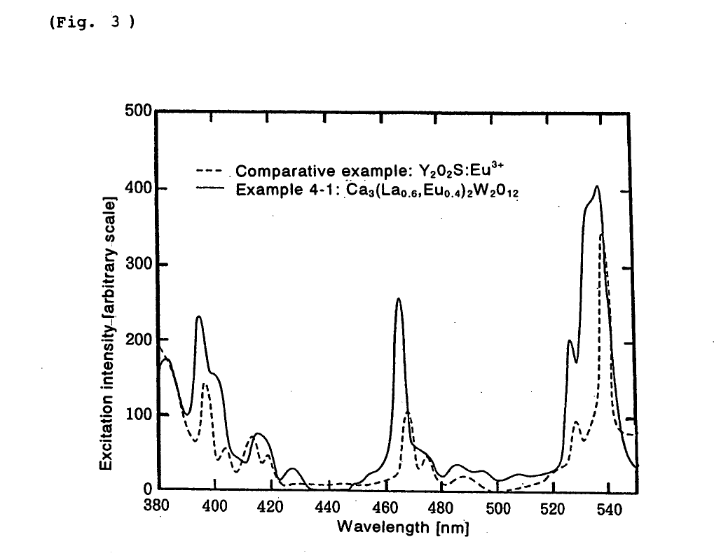

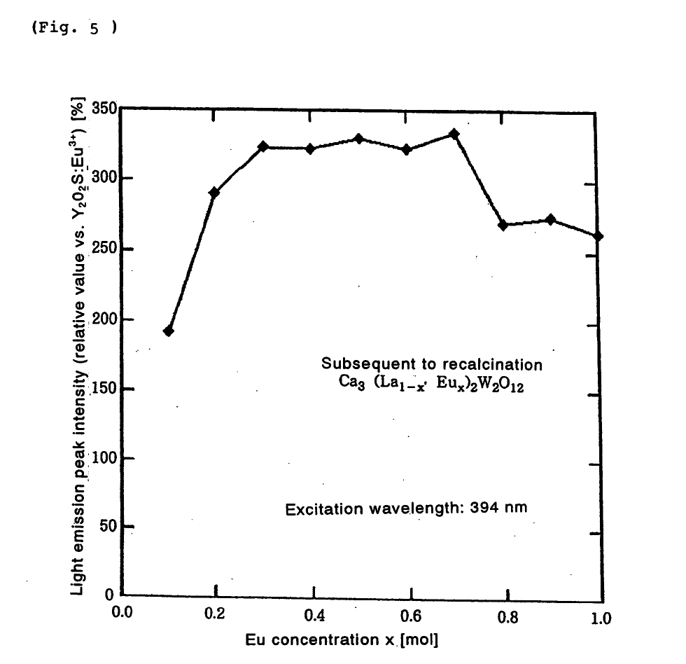

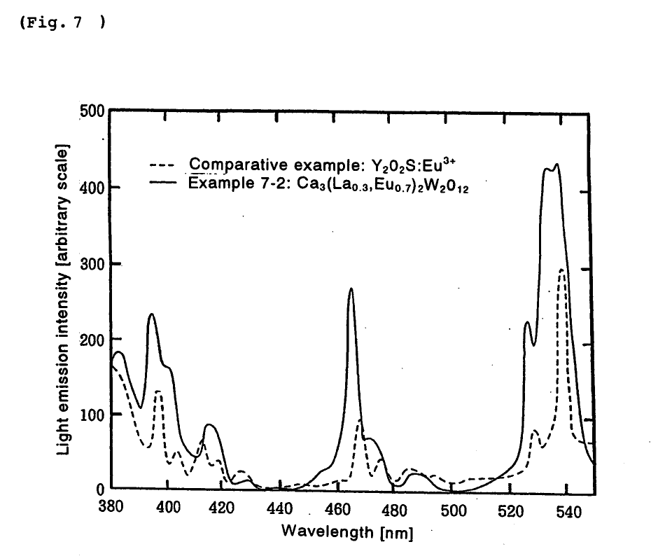

As for the red fluorescent material of the present invention, as can be seen from FIG. 1, FIG. 5, Table 1 and Table 2, the light emission peak intensity is dependent on the concentration of Eu, namely, x, where the light emission peak intensity of Comparative Example of Y₂O₂S:Eu³⁺ is constrained to be 100. On the other hand, from the excitation spectra shown in FIG. 3 and FIG. 7, it has been shown that the red fluorescent material of the present invention is excited the wavelength region of the light emission of the ultraviolet light emitting diode from 350 to 410 nm, in particular, in the wavelength region at around 390 nm in which the light emission efficiency of the ultraviolet emitting diode is good, and efficiently emits red light. It has also been shown that the red fluorescent material of the present invention efficiently converts into red light the light in the blue light (430 nm to 490 nm) and green light (520 nm to 570 nm) regions, in particular, the light at around 465 nm in the wavelength region of the blue light emitting diode and the light at around 538 nm in the wavelength region of the green light emitting diode.

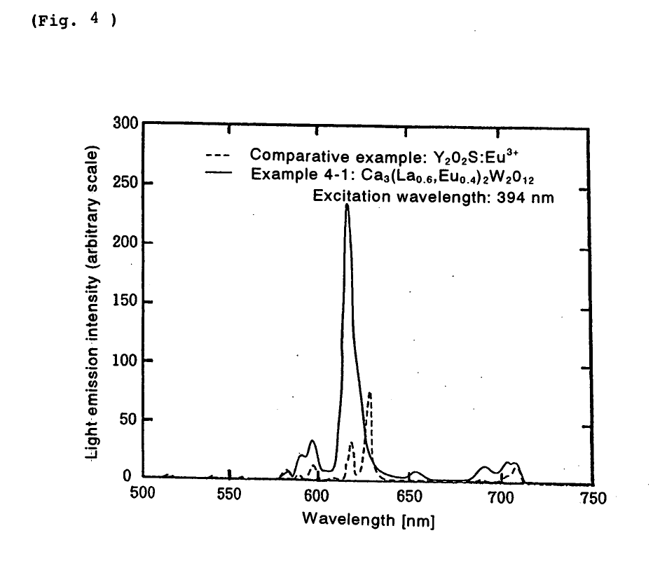

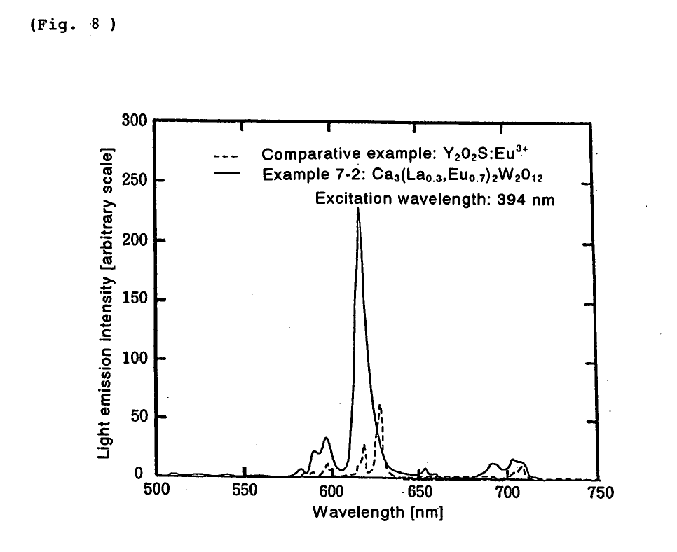

As shown in FIG. 4 and FIG. 8, in the excitation at 394 nm, Examples 4-1 and 7-2 exhibited light emission peak intensities of about 300% of the light emission peak intensity of Comparative Example, exhibiting high visibility red light and having a chromaticity comparable with that of Comparative Example. Additionally, these Examples are larger in light emitting area as compared to Comparative Example, and hence can find an advantage such that there is exhibited a relatively high luminance in comparison with the light emission peak intensity. Additionally, when a comparison is made in terms of the X and Y values, namely, the tristimulus values in the XYZ color system, it is shown that Example 4-1 exhibits an X value to be about 510% of that in Comparative Example, and also a Y value to be about 470% of that in Comparative Example.

As can be seen from FIG. 1, FIG. 5, Table 1 and Table 2, in the red fluorescent material of the present invention, composed of a europium doped calcium lanthanum tungstate, represented by the general formula of Ca₃(La₁₋ₓ,Euₓ)₂W₂0₁₂ (0<x≦1), recalcination increases the light emission intensity.

The red fluorescent material of the present invention, composed of the europium doped calcium lanthanum tungstate, represented by the general formula of Ca₃(La₁₋ₓ,Euₓ)₂W₂0₁₂ can achieve the effect of the present invention for the Eu concentration of 0<x≦1; the Eu concentration is preferably 0.1<x≦0.9, and more preferably 0.3<x≦0.7 particularly in the case where recalcination is conducted.

A second embodiment is an article in which a fluorescent material in which Ce is doped in a YAG based oxide matrix lattice (YAG:Ce fluorescent material), known by a composition formula of (Y,Gd)₃(Al,Ga)₅O₁₂, emitting yellow light to be complementary to blue and green light, and the red fluorescent material of the present invention composed of the europium doped calcium lanthanum tungstate, represented by the general formula of Ca₃(La₁₋ₓ,Euₓ)₂W₂0₁₂ (0<x≦1), are dispersed in the sealing resin portion enclosing a blue light emitting diode using a nitride semiconductor.

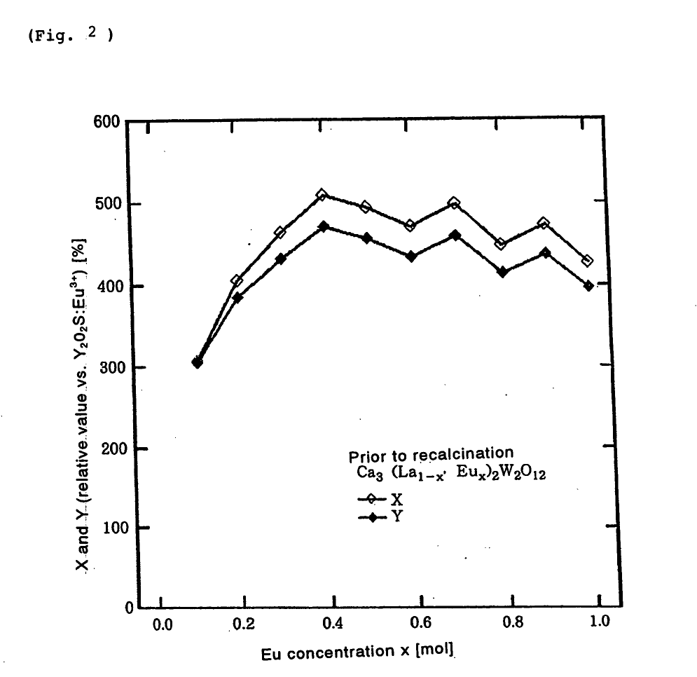

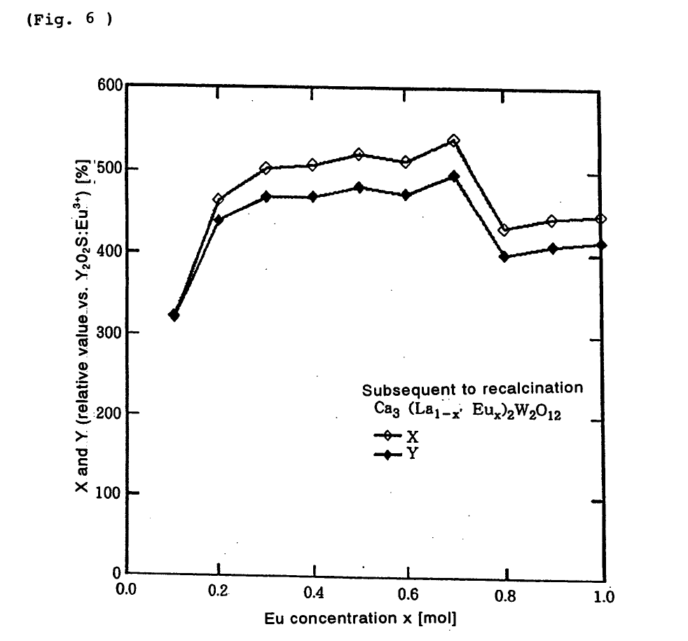

The red fluorescent material of the present invention, composed of the europium doped calcium lanthanum tungstate, represented by the general formula of Ca₃(La₁₋ₓ,Euₓ)₂W₂0₁₂ (0<x≦1), efficiently converts blue light at around 465 nm and green light at around 538 nm into red light, as shown in FIG. 2 and FIG. 6.

Additionally, the YAG based yellow fluorescent material emits nearly yellow light (the wavelength: 590 nm), and emits light over a broad wavelength range, so that the red fluorescent material of the present invention composed of the europium doped calcium lanthanum tungstate, represented by the general formula of Ca₃(La₁₋ₓ,Euₓ)₂W₂0₁₂ emits red light by receiving the fluorescence from the YAG based yellow fluorescent material in addition to the light emitted from a blue light emitting diode. Consequently, there can be overcome problems of the conventional technique, namely, poor color reproducibility and low color rendering properties caused by insufficient light emitting intensity.

A third embodiment of the present invention is an article in which an ultraviolet light emitting diode is disposed inside a transparent resin portion formed on a transparent substrate (a front panel), and the red fluorescent material of the present invention is used in the red fluorescent material of a three-wavelength type white light emitting diode in which three visible light emitting fluorescent materials respectively emitting red light, green light and blue light caused ultraviolet light are mixed in the transparent resin portion. The conventional Y₂O₂S:Eu³⁺ red fluorescent material has a problem such that the light emission efficiency is low; wherein receiving the wavelength range around 390 nm where an ultraviolet light emitting diode emits light efficiently; however, the red fluorescent material of the present invention composed of the europium doped calcium lanthanum tungstate, represented by the general formula of Ca₃(La₁₋ₓ,Euₓ)₂W₂0₁₂ (0<x≦1), emits light efficiently wherein receiving the wavelength range around 390 nm where a ultraviolet light emitting diode emits light efficiently, as shown in FIG. 1, FIG. 5, Table 1 and Table 2.

By use of the red fluorescent material of the present invention composed of the europium doped calcium lanthanum tungstate, represented by the general formula of Ca₃(La₁₋ₓ,Euₓ)₂W₂0₁₂ (0<x≦1), a white light emitting diode satisfactory in color reproducibility, high in color rendering properties and high in light emission efficiency is obtained.

The white light emitting diode satisfactory in color reducibility, high in color rendering properties and high in light emission efficiency can be used for lighting devices, light emitting diode displays, backlight unit of a liquid crystal display and the like.

### EXAMPLES

Detailed description will be made on the red fluorescent material of the present invention composed of the europium doped calcium lanthanum tungstate, formed of the europium doped calcium lanthanum tungstate, composed of calcium (Ca), lanthanum (La), europium (Eu), tungsten (W) and oxygen (O), and represented by the general formula of Ca₃(La₁₋ₓ,Euₓ)₂W₂0₁₂ (0<x≦1).

(Description of the Fabrication Methods of Examples)

Next, description will be made on the fabrication methods of Examples.

At the beginning, as the raw materials for synthesis of the fluorescent materials, there are used calcium compounds such as calcium carbonate (CaCO₃), lanthanum compounds such as lanthanum oxide (La₂O₃), europium compounds such as europium oxide (Eu₂O₃) and tungsten compounds such as tungsten oxide (WO₃). These raw materials are weighed out according to the composition formula, collected and mixed together fully by a wet or dry method.

The mixture thus obtained is charged in a heat resistant vessel such as an alumina crucible and a platinum crucible, calcined in the air at 1250 to 1400° C. for 3 to 10 hours; the calcined substance thus obtained is pulverized, washed, dried and sieved out, and thus the fluorescent material of the present invention is obtained. Incidentally, calcination may be conducted at 900 to 1100° C. for 3 to 6 hours, before calcination, as preliminary calcinations.

Additionally, recalcination of the obtained fluorescent material powder leads to an enhanced effect. It is preferable that preliminary calcination, calcination, and recalcination each are calcination conducted in an oxidative atmosphere.

Table 1 shows the compositions and the light emission properties, and in Example 4-1, an example fabricated in the present invention is described. As the raw materials, powders of CaCO₃, La₂O₃, Eu₂O₃ and WO₃ were used and weighed out. The respective raw materials weighed out were as follows so as to achieve the desired composition of Ca₃(La_{0.6}, Eu_{0.4})₂W₂O₁₂: CaCO₃=6.4754 g, WO₃=10.0000 g, La₂O₃=4.2159 g, Eu₂O₃=3.0358 g; these were placed in an alumina mortar and mixed fully with an alumina pestle in a dry mixing operation. The mixed powder was charged in an alumina crucible, the crucible was set in an electric furnace for calcination in the air at 1350° C. for 6 hours. After calcination, the crucible was cooled slowly, and the calcined substance thus obtained was subjected to pulverization, and thus the desired sample was obtained. The sample thus obtained was subjected to recalcination at 1350° C. for 6 hours, pulverization, sieving out, and thus yielding a final sample to be Example 4-2.

It is preferable that recalcination is conducted at a temperature equal to or higher than the calcination temperature.

Example 1-1 to Example 10-1 are the samples before being subjected to recalcination, and the samples having been subjected to recalcination of the respective Example 1-1 to Example 10-1 are Example 1-2 to Example 10-2.

In all the examples of Example 1-2 to Example 10-2 having been subjected to recalcination, improvement in light emission properties was found. In particular, Examples 6-2 and 7-2 exhibited remarkable improvement.

From the results on Example 1-2 to Example 10-2 having been subjected to recalcination, through carrying out relcacination, red fluorescent materials have been obtained which are as very small as ±1.6% in the variation of the light emission peak intensity for the variation of the Eu concentration in the Eu concentration range from 0.3 mol to 0.7 mol, and small in the light emission peak intensity variation caused by unevenness in fabrication.

Consequently, the use of the fluorescent material of the present invention as the red fluorescent material in white light emitting elements makes it possible to achieve higher efficiency. Additionally, as is clear from FIG. 3 and FIG. 7, Example 4 can convert blue light and green light into red light with a higher efficiency as compared to Comparative Example.

TABLE 1
Comparison of light emission properties under the excitation at 394 nm
between Y₂0₂S:Eu³⁺ (Comparative Example) and Ca₃(La₁₋ₓ,Euₓ)₂W₂0₁₂
(Examples 1-1 to 10-1)

| | | Light | Tristimulus | |
|---|---|---|---|---|
| | | emission | values in | |
| | | peak | XYZ color | |
| | | intensity | system | |
| | Composition | [%] | X [%] | Y [%] |
| Comparative | Y₂O₂S:Eu³⁺ | 100 | 100 | 100 |
| example | | | | |
| Example 1-1 | Ca₃(La_{0.9},EU_{0.1})₂W₂O₁₂ | 168 | 307 | 305 |
| Example 2-1 | Ca₃(La_{0.8},Eu_{0.2})₂W₂O₁₂ | 233 | 406 | 385 |
| Example 3-1 | Ca₃(La_{0.7},EU_{0.3})₂W₂O₁₂ | 271 | 464 | 432 |
| Example 4-1 | Ca₃(La_{0.6},Eu_{0.4})₂W₂O₁₂ | 296 | 509 | 471 |
| Example 5-1 | Ca₃(La_{0.5},Eu_{0.5})₂W₂O₁₂ | 288 | 494 | 456 |
| Example 6-1 | Ca₃(La_{0.4},Eu_{0.6})₂W₂O₁₂ | 273 | 471 | 434 |
| Example 7-1 | Ca₃(La_{0.3},Eu_{0.7})₂W₂O₁₂ | 285 | 498 | 459 |
| Example 8-1 | Ca₃(La_{0.2},Eu_{0.8})₂W₂O₁₂ | 254 | 448 | 414 |
| Example 9-1 | Ca₃(La_{0.1},Eu_{0.9})₂W₂O₁₂ | 265 | 473 | 437 |
| Example 10-1 | Ca₃(La_{0.0},Eu_{1.0})₂W₂O₁₂ | 229 | 427 | 397 |
| | (Ca₃Eu₂W₂0₁₂) | | | |

TABLE 2
Comparison of light emission properties under the excitation at 394 nm
between Y₂0₂S:Eu³⁺ (Comparative Example) and Ca₃(La₁₋ₓ,Euₓ)₂W₂0₁₂
(Examples 1-2 to 10-2)

| | | Light | Tristimulus | |
|---|---|---|---|---|
| | | emission | values in | |
| | | peak | XYZ color | |
| | | intensity | system | |
| | Composition | [%] | X [%] | Y [%] |
| Comparative | Y₂O₂S:Eu³⁺ | 100 | 100 | 100 |
| example | | | | |
| Example 1-2 | Ca₃(La_{0.9},EU_{0.1})₂W₂O₁₂ | 193 | 323 | 321 |
| Example 2-2 | Ca₃(La_{0.8},Eu_{0.2})₂W₂O₁₂ | 291 | 464 | 439 |
| Example 3-2 | Ca₃(La_{0.7},EU_{0.3})₂W₂O₁₂ | 324 | 503 | 468 |
| Example 4-2 | Ca₃(La_{0.6},Eu_{0.4})₂W₂O₁₂ | 323 | 507 | 469 |
| Example 5-2 | Ca₃(La_{0.5},Eu_{0.5})₂W₂O₁₂ | 330 | 521 | 482 |
| Example 6-2 | Ca₃(La_{0.4},Eu_{0.6})₂W₂O₁₂ | 323 | 513 | 473 |
| Example 7-2 | Ca₃(La_{0.3},Eu_{0.7})₂W₂O₁₂ | 334 | 539 | 497 |
| Example 8-2 | Ca₃(La_{0.2},Eu_{0.8})₂W₂O₁₂ | 271 | 433 | 400 |
| Example 9-2 | Ca₃(La_{0.1},Eu_{0.9})₂W₂O₁₂ | 275 | 444 | 411 |
| Example 10-2 | Ca₃(La_{0.0},Eu_{1.0})₂W₂O₁₂ | 264 | 448 | 416 |
| | (Ca₃Eu₂W₂0₁₂) | | | |

1. A red fluorescent material comprising a europium doped calcium lanthanum tungstate represented by a general formula of Ca₃(La₁₋ₓ,Euₓ)₂W₂0₁₂ (0<x≦1).

2. A white light emitting diode comprising:
an ultraviolet light emitting diode; and
a blue fluorescent material, a green fluorescent material and a red fluorescent material, respectively emitting blue, green and red fluorescence and disposed at least in an area which is irradiated with said ultraviolet light and a portion of the light emitting surface of said ultraviolet light emitting diode to emit white light owing to said blue, green and red fluorescence,
wherein said red fluorescent material is composed of a red fluorescent material comprising a europium doped calcium lanthanum tungstate represented by the general formula of Ca₃(La₁₋ₓ,Euₓ)₂W₂0₁₂ (0<x≦1).

3. A white light emitting diode comprising:
a light emitting diode emitting light in any of the wavelength regions ranging at least from blue to green light; and
a yellow fluorescent material emitting yellow light caused by and complementary to said diode-emitted light and a red fluorescent material emitting red light, both fluorescent materials being disposed at least in an area which is irradiated with the light emitted from said light emitting diode and a portion of the light emitting surface of said light emitting diode.

4. The white light emitting diode according to claim 3, wherein said red fluorescent material receives said yellow fluorescence and emits red light.

5. The white light emitting diode according to claim 4, wherein said yellow fluorescent material is a YAG based yellow fluorescent material.

6. The white light emitting diode according to any one of claims 3 to 5, wherein said red fluorescent material is a red fluorescent material comprising a europium doped calcium lanthanum tungstate represented by the general formula of Ca₃(La₁₋ₓ,Euₓ)₂W₂0₁₂ (0<x≦1).

7. A lighting system using the white light emitting diode according to claim 2.

8. A lighting system using the white light emitting diode according to claim 3.

9. A light emitting diode display using the white light emitting diode according to claim 2.

10. A light emitting diode display using the white light emitting diode according to claim 3.

11. A backlight unit of a liquid crystal display, wherein the white light emitting diode according to claim 2 is used.

12. A backlight unit of a liquid crystal display, wherein the white light emitting diode according to claim 3 is used.

13. A liquid crystal display using the backlight unit according to claim 11.

14. A liquid crystal display using the backlight unit according to claim 12.

15. A method for producing a red fluorescent material comprising a europium doped calcium lanthanum tungstate, obtained by calcing together at least a calcium compound, a lanthanum compound, a europium compound and a tungsten compound, and represented by the general formula of Ca₃(La₁₋ₓ,Euₓ)₂W₂0₁₂ (0<x≦1),
wherein the calcined substance thus obtained is recalcined at least after pulverization thereof.
